(19) United States
(12) Patent Application Publication
(10) Pub. No.: US 2024/0058952 A1
(43) Pub. Date: Feb. 22, 2024

(54) CONTROLLER FOR SUBSTRATE TRANSFER ROBOT AND CONTROL METHOD FOR JOINT MOTOR

(71) Applicant: KAWASAKI JUKOGYO KABUSHIKI KAISHA, Kobe-shi, Hyogo (JP)

(72) Inventors: Hiroki IMANISHI, Kobe-shi (JP); Shinya KITANO, Kobe-shi (JP)

(73) Assignee: KAWASAKI JUKOGYO KABUSHIKI KAISHA, Kobe-shi, Hyogo (JP)

(21) Appl. No.: 18/269,324

(22) PCT Filed: Nov. 18, 2021
(86) PCT No.: PCT/JP2021/042425

§ 371 Date: Jun. 23, 2023

(30) Foreign Application Priority Data
Dec. 25, 2020 (JP) 2020-217918

(51) Int. Cl. B25J 9/16; B25J 11/00

(52) U.S. Cl. CPC B25J 9/1612; B25J 11/0095; B25J 9/1679

(57) ABSTRACT

A controller controls a substrate transfer robot whose joint axis is oriented in a vertical direction. The joint motor that drives the joint is switchable in a direction of rotation. The controller corrects a position of a hand in at least one of the cases of picking a substrate and placing a substrate based on positional misalignment information. The controller controls the hand to pass through a relay position before the hand reaches a corrected position that is the position of the hand after correction. The controller controls the hand to reach the relay position by driving the joint in one direction by the joint motor, and the hand to reach the corrected position from the relay position by driving the joint in the same one direction only by the joint motor.

### TECHNICAL FIELD

The present disclosure relates to control of a motor that drives a joint in a substrate transfer robot whose joint has a vertical axis.

### BACKGROUND ART

Conventionally, it has been known that in a substrate transfer system, when a positional misalignment occurs in a substrate to be transferred, a configuration to eliminate the positional misalignment by changing a position of the hand in picking or placing a substrate is used.

PTL 1 discloses a wafer transfer system having a pre-aligner apparatus. PTL 1 mentions a configuration in which the pre-aligner apparatus not only aligns a notch of the wafer, but also detects and calculates a center misalignment amount and performs center alignment. In PTL 1, an example of a method to perform the center alignment is described in which the wafer transfer apparatus shifts (corrects) a wafer receiving position relative to a center of rotation of the pre-aligner apparatus based on information of a center misalignment amount, and moves an end-effector of the transfer apparatus so that the center position of the wafer is aligned when the wafer is received.

### PRIOR-ART DOCUMENTS

### Patent Documents

PTL 1: Japanese Patent Application Laid-Open No. 2010-199245.

### SUMMARY OF THE INVENTION

### Problems to be Solved by the Invention

In the configuration of PTL 1, a wafer receiving position can be changed in various ways depending on an amount of center misalignment. Generally, a reduction gear or other device is located between a joint motor and a joint of the robot. Gear transmission mechanisms are often used as reduction gears. When a direction of rotation of the joint is switched during a process of hand movement, positional accuracy decreases due to backlash of the gear train, and the center misalignment may not be accurately corrected.

The present disclosure was made in view of the above circumstances, and the purpose of the present disclosure is to eliminate a positional misalignment with high accuracy in a stable manner, no matter how the positional misalignment of the substrate occurs.

### Means for Solving the Problems

The problem to be solved by this disclosure is as described above, and the means for solving this problem and effects thereof are described below.

According to a first aspect of the present disclosure, a controller for a substrate transfer robot having the following configuration is provided. That is, the controller controls the substrate transfer robot including a hand, a joint, and a joint motor. The hand is capable of holding a substrate. The axis of the joint is oriented in a vertical direction. The joint motor drives the joint. The joint motor is switchable in a direction of rotation. The controller corrects a position of the hand in at least one of the cases of picking the substrate and placing the substrate based on positional misalignment information indicating a positional misalignment of the substrate. The controller controls the hand to pass through a relay position before the hand reaches a corrected position that is the position of the hand after correction. The controller controls the hand to reach the relay position by driving the joint in one direction by the joint motor, and the hand to reach the corrected position from the relay position by driving the joint in the same one direction only by the joint motor.

This allows for stable avoidance of adverse effects due to backlash in the joint drive portion. Thus, the positional accuracy gets better when the substrate is picked/placed.

According to a second aspect of the present disclosure, a robot system comprising the controller and the substrate transfer robot is provided.

This provides a robot system that can improve the positional accuracy of the substrate in a stable manner.

According to a third aspect of the present disclosure, a control method for a joint motor is provided, which is as follows. That is, the control method for a joint motor controls the joint motor in a substrate transfer robot including a hand, a joint, and a joint motor. The hand is capable of holding a substrate. The axis of the joint is oriented in a vertical direction. The joint motor drives the joint. The joint motor is switchable in a direction of rotation. The control method includes correcting a position of the hand in at least one of the cases of picking the substrate and placing the substrate based on positional misalignment information indicating a positional misalignment of the substrate. The control method includes controlling the hand to pass through the relay position before the hand reaches a corrected position that is the position of the hand after correction. The control method includes controlling the hand to reach the relay position by driving the joint in one direction by the joint motor, and the hand to reach the corrected position from the relay position by driving the joint in the same one direction only by the joint motor.

This allows for stable avoidance of adverse effects due to backlash in the joint drive portion. Therefore, the positional accuracy gets better when the substrate is picked/placed.

### Effects of the Invention

According to the present disclosure, no matter how a positional misalignment of the substrate occurs, the positional misalignment can be eliminated with high stability and accuracy.

### BRIEF DESCRIPTION OF THE DRAWINGS

FIG. 1 is a perspective diagram showing an overall configuration of a robot system according to one embodiment of the present disclosure.

FIG. 2 is a perspective diagram showing a configuration of a robot.

FIG. 3 is a block diagram showing a configuration of a part of the robot system.

FIG. 4 is a plan view showing a comparative example regarding relay positions before picking a wafer from a positional misalignment detector.

FIG. 5 is a plan view showing the relay positions of the present embodiment.

FIG. 6 is a graph showing an example of the relation between a range of a picking position and a relay position at each of three joints.

### EMBODIMENT FOR CARRYING OUT THE INVENTION

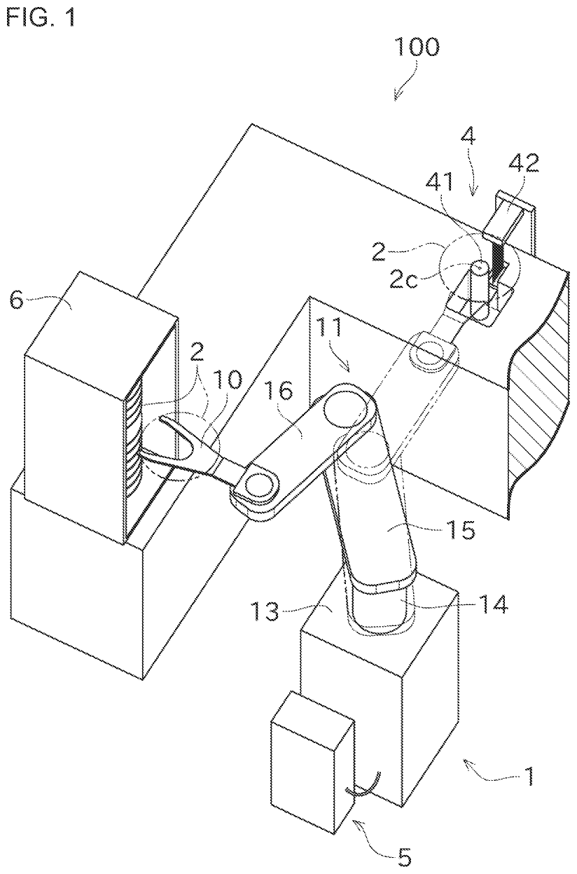

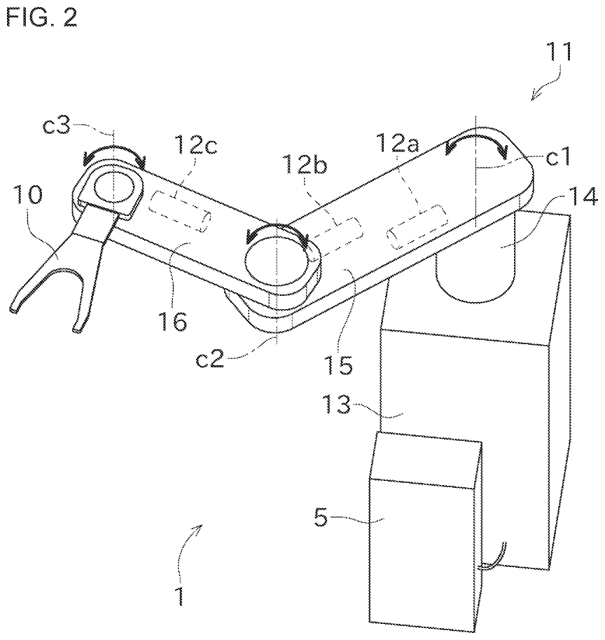

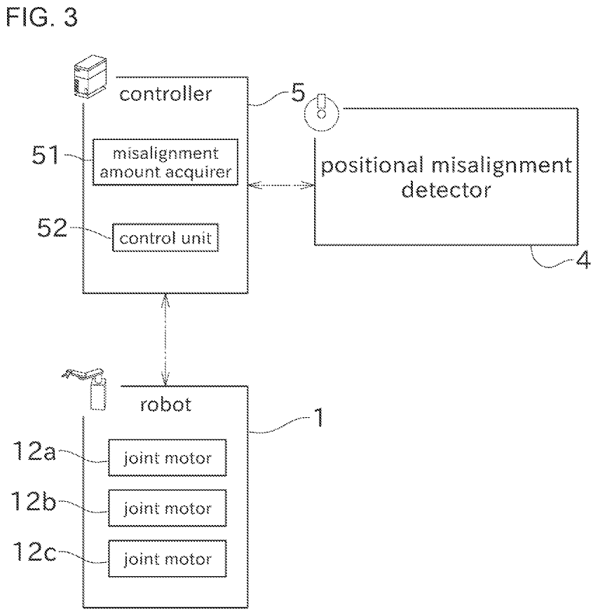

Next, the disclosed embodiments will be described with reference to the drawings. FIG. 1 is a perspective diagram showing a configuration of a robot system 100 in accordance with one embodiment of the disclosure. FIG. 2 is a perspective diagram showing a configuration of a robot 1. FIG. 3 is a block diagram showing a configuration of a part of the robot system 100.

The robot system 100 shown in FIG. 1 is a system that allows the robot 1 to perform work in a clean room or other work space.

The robot system 100 includes a robot 1, a positional misalignment detector (substrate aligner) 4, and a controller (control unit) 5.

The robot 1 functions, for example, as a wafer transfer robot that transfers a wafer 2 stored in a storage container 6 in this embodiment, the robot 1 is realized by a SCARA type horizontal articulated robot. SCARA is an abbreviation for Selective Compliance Assembly Robot Arm.

The wafer 2 transferred by the robot 1 is a type of substrate. The water 2 is shaped as a thin circular plate.

As shown in FIG. 2, the robot 1 includes a hand (holder) 10, a manipulator 11, and joint motors 12a, 12b, 1.2c.

The hand 10 is a type of end-effector and is generally V-shaped or U-shaped in plan view. The hand 10 is supported at a tip of the manipulator 11 (specifically, a second link 16 described below). The hand 10 rotates around a third axis c3 extending in a vertical direction with respect to the second link 16.

The manipulator 11 is primarily includes a base 13, an elevation shaft 14, a first link 15, and the second link 16.

The base 13 is fixed to the ground (for example, a floor of a clean room). The base 13 functions as a base member supporting the elevation shaft 14.

The elevation shaft 14 moves in the vertical direction with respect to the base 13. This elevation allows a height of the first link 15, the second link 16, and the hand 10 to be changed.

The first link 15 is supported on an upper part of the elevation shaft 14. The first link 15 rotates around a first axis c1 extending in a vertical direction with respect to the elevation shaft 14. This allows a posture of the first link 15 to be changed in a horizontal plane.

The second link 16 is supported at a tip of the first link 15. The second link 16 rotates around the second axis c2 extending in the vertical direction with respect to the first link 15. This allows a posture of the second link 16 to be changed within the horizontal plane.

Thus, the manipulator 11 is configured to include three joints whose axes are oriented in the vertical direction. In the following, each joint is sometimes referred to with the reference number of the center axis c1, c2, c3 to identify each joint.

Joint motors 12a, 126, and 12c drive joints c1, c2, and c3, respectively. This allows the position and posture of the hand 10 in plan view to be changed in various ways. The joint motors 12a, 12b, 12c are configured as servo motors, a type of electric motor. The joint motor 12a, which drives the joint c1, is located in the first link 15.

The joint motor 12b, which drives the joint c2, is located in the first link 15. The joint motor 12c, which drives the joint c3, is located in the second link 16. However, the layout of each motor is not limited to the above.

The positional misalignment detector 4 comprises, for example, a pre-aligner (wafer aligner). As shown in HQ. 1, the positional misalignment detector 4 includes a rotary table 41 and a line sensor 42.

The rotary table 41 can rotate the wafer 2 by an electric motor or the like, which is not shown in the figure. The rotary table 41 rotates with the wafer 2 placed thereon. The rotary table 41 is, for example, cylinder-shaped, as shown in FIG. 1. However, it is not limited to this.

The line sensor 42 comprises, for example, a transmission type sensor having a light projector and a light receiver. The light projector and the light receiver are disposed opposite each other and disposed at a predetermined distance in the vertical direction. The line sensor 42 projects detection light by the light projector arranged in a radial direction of the rotary table 41 and receives detection light by the light receiver provided at a lower position of the light projector. The detection light can be, for example, laser light. When the wafer 2 is placed on the rotary table 41, the outer edge of the wafer 2 is located between the light projector and the light receiver.

The line sensor 42 is electrically connected to a misalignment amount acquirer 51 described below. The line sensor 42 transmits a detection result of the light receiver to the misalignment amount acquirer 51. As described in detail below, a change in the detection result of the light receiver when the rotary table 41 is rotated corresponds to a shape of the outer edge of the wafer 2. From the shape of this outer edge, a positional misalignment of the center of the wafer 2 from a center of rotation of the rotary table 41 is detectable. Therefore, in the positional misalignment detector 4, a detection reference position for the positional misalignment is the center of rotation of the rotary table 41. The misalignment amount acquirer 51 acquires a misalignment amount of the wafer 2 based on the detection result of the light receiver.

The line sensor 42 is not limited to a transmission type sensor, for example, it may comprise a reflective sensor.

As shown in FIG. 3, the controller 5 includes the misalignment amount acquirer 51 and a control unit 52. The controller 5 is configured as a known computer including a CPU, a ROM, a RAM, and an auxiliary storage, and the like. The auxiliary storage is configured as an HDD, an SSD, etc., for example. The auxiliary storage stores a robot control program and the like for realizing the control method of the joint motors 12a, 126, 12c of the present disclosure. These hardware and software work cooperatively, so that the controller 5 can be operated as the misalignment amount acquirer 51 and the control unit 52, etc.

The misalignment amount acquirer 51 acquires the misalignment amount of the wafer 2 based on the detection result from the line sensor 42, as described above.

The control unit 52 controls the respective drive motors that drive various parts of the robot 1 described above by outputting command values according to a predetermined operation program or a movement command input by a user, to move the hand 10 to a predetermined command position. The drive motors include the joint motors 12a, 12b, 12c described above as well as the electric motor, not shown in the figure, to displace the elevation shaft 14 in the vertical direction.

Next, a method of acquiring the positional misalignment of the wafer 2 using the positional misalignment detector 4 will be described in detail.

The control unit 52 controls the robot 1 to pick the wafer 2 from the storage container 6 and transfer the wafer 2 to the rotary table 41 of the positional misalignment detector 4. After the wafer 2 is placed on the rotary table 41, the control unit 52 controls the robot 1 to wait at a predetermined position, which is a short distance away from the positional misalignment detector 4. This position can be regarded as a relay position through which the hand 10 passes after placing the wafer 2 on the rotary table 41 and before picking the wafer 2 from the rotary table 41. The details of the relay position are described later.

Once the wafer 2 is placed on the rotary table 41, the positional misalignment detector 4 rotates the rotary table 41 while continuously detecting a peripheral edge position of the wafer 2 by the line sensor 42. When a center axis 2c of the wafer 2 is perfectly aligned with the center of rotation of the rotary table 41, the peripheral edge position of the wafer 2 detected by the line sensor 42 is constant regardless of a rotation phase of the rotary table 41. If the center of the wafer 2 is misaligned with the center of rotation of the rotary table 41, the peripheral edge position of wafer 2 changes in conjunction with the rotation of the rotary table 41 with an amplitude corresponding to a distance of misalignment. A direction of the misalignment can be acquired, for example, based on the phase of the rotary table 41 in which the peripheral edge position is at its maximum or minimum.

The misalignment amount acquirer 51 acquires the misalignment amount based on the detection result of the line sensor 42. The misalignment amount indicates in which direction and by which distance the center axis 2c of the wafer 2 shown in FIG. 1 is misaligned with respect to the center of rotation of the rotary table 41. The misalignment amount can be described, for example, as a plane vector (ox, oy). Details are omitted since calculation methods are well known, but this misalignment amount can be acquired by performing a geometric calculation. The misalignment amount acquirer 51 outputs the acquired misalignment amount to the control unit 52.

An original position at which the wafer 2 is picked by the hand 10 is a position at which its center matches the center of rotation of the rotary table 41. However, if the hand 10 picks the wafer 2 at this position, as described above, if there is a positional misalignment of the wafer 2, this positional misalignment directly causes the positional misalignment of the wafer 2 with respect to the hand 10. Therefore, the control unit 52 corrects the position at which the hand 10 picks the wafer 2 based on the misalignment amount input from the misalignment amount acquirer 51, The misalignment amount is information indicating the positional misalignment of the wafer 2 (positional misalignment information). Correction can be realized by displacing the hand 10 from its original position according to the acquired misalignment amount of wafer 2. In the following, a position after correction may be referred to as a picking position (corrected position).

The control unit 52 moves the hand 10 from the relay position described above to the picking position. When the movement is completed, the hand 10 picks the wafer 2 from the rotary table 41. This allows the hand 10 to hold the wafer 2 with the center axis 2c of the wafer 2 aligned with the center of the hand 10. The control unit 52 controls the robot 1 to transfer the wafer 2 held by the hand 10 to an appropriate destination.

Next, the relay position of the hand 10 when the positional misalignment detector 4 is detecting the positional misalignment is described in detail.

While the positional misalignment detector 4 is detecting the positional misalignment of the wafer 2, the hand 10 waits at a position that does not interfere with the detection of the positional misalignment. The position where the hand 10 waits (i.e., the relay position) is determined to be common regardless of the misalignment amount of the wafer 2. This simplifies the control of the robot 1. It is preferable for the hand 10 to wait near the rotary table 41 because the wafer 2 can be immediately picked.

At the time when the hand 10 is waiting at the relay position, the misalignment amount of the wafer 2 is unknown. However, if the misalignment amount of the wafer 2 exceeds a predetermined range, either the misalignment amount cannot be detected by the positional misalignment detector 4 or a detected value becomes abnormal, causing the robot system 100 to stop abnormally. Therefore, the position at which the hand 10 pickes the wafer 2 from the positional misalignment detector 4 is substantially within the predetermined size range.

Once the misalignment amount of the wafer 2 is detected by the positional misalignment detector 4, an actual position of the hand 10 when the wafer 2 is picked from the positional misalignment detector 4 is determined. This position is the picking position described above. The hand 10 is moved from the relay position to the picking position by rotating one or more of the three joint motors 12a, 12b, 12c in an appropriate direction.

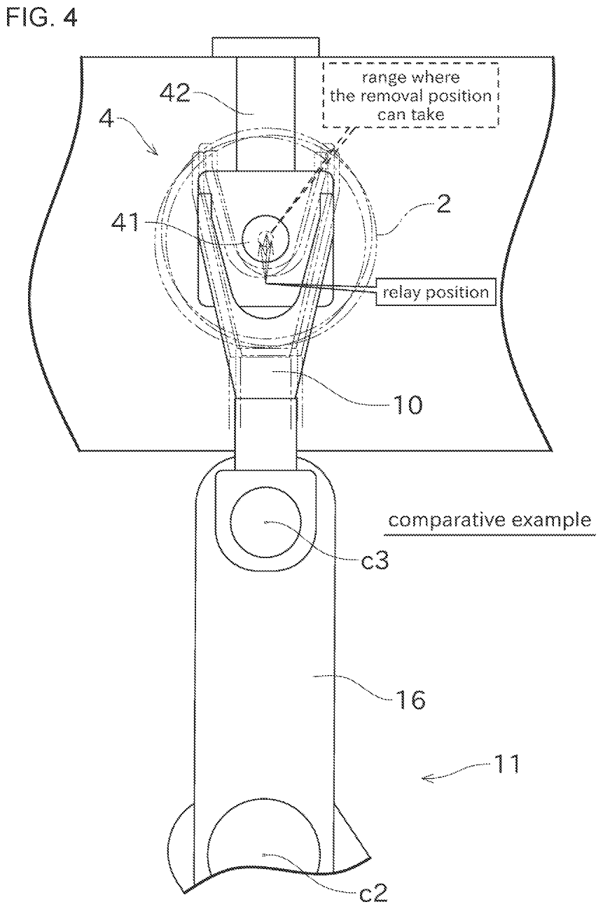

The relay position can basically be set at any desired position. Generally, a shorter distance from the relay position to the picking position is preferable. Considering this point of view, as shown in the comparative example in FIG. 4, it is preferable to set the relay position of the hand 10 at a central or average position so that the picking position is a relatively short travel distance in any case.

However, when the relay position is set in this manner, the directions of rotation of joints c1, c2, c3 for moving the hand 10 from the relay position to the picking position will change according to in which direction the misalignment of the wafer 2 occurs from the center of rotation of the rotary table 41. This means that the directions of rotation of the respective joint motors 12a, 12b, 12c are not constant, and the directions of rotation are opposite in some cases, such as in a positive direction at one picking position and in a negative direction at another picking position.

In the present specification, the plus direction means the direction that is clockwise with respect to the joint, and the minus direction means the direction that is counterclockwise. However, the definitions of the positive and negative directions are for convenience only.

A gear transmission mechanism (for example, a reduction gear) is located between each joint motor 12a, 12b, 12c and the corresponding respective joint c1, c2, c3. If the direction of rotation is switched in any of the three joint motors 12a, 12h, 12c, positional accuracy of the hand 10 decreases due to the backlash of the gear transmission mechanism. As a result, the misalignment of the wafer 2 acquired by the positional misalignment detector 4 cannot be cancelled in a stable and highly accurate manner.

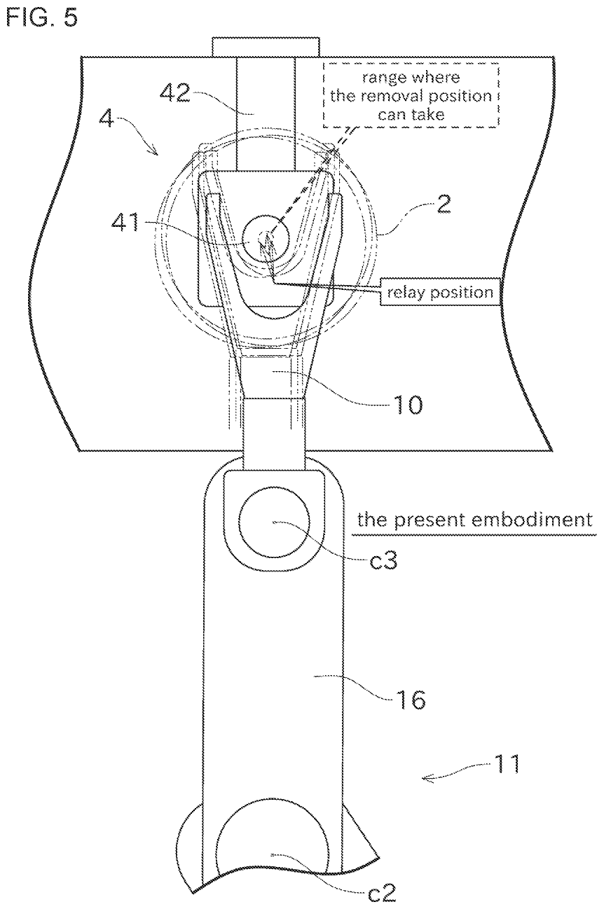

Therefore, in the present embodiment, as shown in FIG. 5, the relay position of the hand 10 is set at a position sufficiently biased to one side with respect to a range where the picking position can take. Therefore, no matter where the picking position is within the given range, the direction of rotation of each of the three joints c1, c2, c3 in which the hand 10 reaches the picking position from the relay position is not affected.

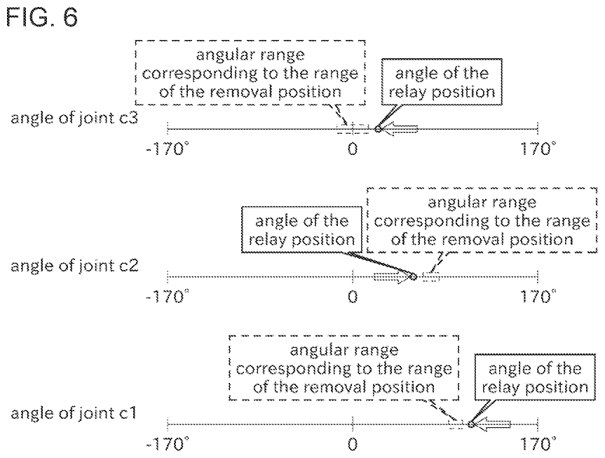

The relay position is defined to be outside the range where the picking position can take. Strictly speaking, in the present embodiment, an angle of the joint corresponding to the relay position of the hand 10 does not fail within an angular range of the joint corresponding to a range of the picking position, and is outside of the angular range to either side. This relation is established for all three joints c1, c2, c3 that the manipulator 11 includes. An example of the relation between the range of the picking position and the relay position in the three joints c1, c2, c3 is shown in FIG. 6 as a conceptual diagram. Focusing on the joint c3 in FIG. 6, no matter where the picking position is in a predetermined range, the joint c3 is always driven only in the negative direction until the hand 10 reaches the picking position from the relay position.

Furthermore, when the hand 10 reaches the relay position, the control unit 52 controls the joints c1, c2, c3 to be driven in same directions as when the hand 10 reaches the picking position from the relay position. The directions of this drive are shown as white arrows in FIG. 6. Focusing on the joint c3, the joint c3 is driven in the minus direction, which causes the hand 10 to reach the relay position. The minus direction, which is a driving direction in this case, is the same as a direction in which the joint c3 is driven from the relay position to the picking position of the hand 10. This relation is established for each of the three joints c1, c2, and c3 of the manipulator 11.

With the above control, the hand 10 is not affected by backlash when the hand reaches the picking position, no matter which position the picking position is. Therefore, the accuracy of the picking position of the hand 10 can be consistently improved.

If the relay position is some distance away from the range of the picking position, the travel distance from the relay position to the picking position can be secured. When the hand 10 is moved from the relay position to the picking position, if an angular change is almost zero with respect to any of the joints el, c2, c3, accuracy in a coincidence between an actual angle and a target angle decreases due to backlash with respect to that joint. In the present embodiment, the relay position is determined so that the angle changes to some extent at any of joints c1, c2, c3 until the hand 10 reaches the picking position from the relay position, no matter where the picking position is within the predetermined range. This allows for good maintenance of the accuracy in coincidence of the axis of each joint, thus preventing a decrease in the positional accuracy of the hand 10 at the picking position.

As described above, the controller 5 controls the robot 1 including the hand 10, the joints c1, c2, c3, and the joint motors 12a, 12b, 12c. The hand 10 is capable of holding the wafer 2. Each axis of the joints c1, c2, c3 is oriented in the vertical direction. The Joint motors 12a, 12b, 12c drive joints c2, c3, respectively. Each of the joint motors 12a, 12b, 12c are switchable in the direction of rotation. The controller 5 corrects the position of the hand 10 in picking the wafer 2 based on the positional misalignment information indicating the positional misalignment of the wafer 2. The controller 5 controls the hand 10 to pass through the relay position before the hand 10 reaches the picking position that is the position of the hand 10 after correction. The controller 5 controls the hand 10 to reach the relay position by driving the joint c3 in one direction by the joint motor 12c, and the hand 10 to reach the picking position from the relay position by driving the joint c3 in the same one direction only by the joint motor 12c. The controller 5 controls the other joint motors 12a and 12b in the same manner.

This allows for stable avoidance of adverse effects of backlash on the correction of the position of the hand 10. This results in the robot 1 with excellent positional accuracy.

In the controller 5 of the substrate transfer robot of the present embodiment, the relay position is distant with respect to a range where the corrected positions can take.

This allows the travel distance from the relay position to the picking position to be secured, which improves the accuracy in a coincidence of axis.

In the controller 5 of the substrate transfer robot of the present embodiment, the one direction is the same no matter what the corrected position is.

This allows for simple control and avoids the adverse effects of backlash.

In the present embodiment, the misalignment amount is information on the positional misalignment of the water 2 set on the positional misalignment detector 4 that is measured by the positional misalignment detector 4. Based on the misalignment amount, the controller 5 corrects the position of the hand 10 when the wafer 2 set on the positional misalignment detector 4 is picked.

This allows the wafer 2 to be picked from the positional misalignment detector 4 so that the positional misalignment is cancelled, immediately after the positional misalignment of the wafer 2 is measured.

The controller 5 of the present embodiment controls the robot 1 so that the hand 10 waits at the relay position after setting the wafer 2 on the positional misalignment detector 4 and before picking the wafer 2 from the positional misalignment detector 4.

This allows a smooth series of operations from setting the wafer 2 on the positional misalignment detector 4 to picking the wafer 2.

While suitable embodiments of the present disclosure have been described above, the above configuration can be modified as follows, for example.

The control described in the above embodiments can be applied to picking a wafer 2 from a location other than the positional misalignment detector 4 (for example, a stage for placing the wafer 2). The misalignment amount of the wafer 2 on the stage can be acquired, for example, by analyzing an image of the wafer 2 taken by a camera, not shown in the figure.

The correction of the position of the hand 10 can be applied not only to picking the wafer 2 from the positional misalignment detector 4, but also, for example, to placing the wafer 2 held by the hand 10 in the storage container 6. The misalignment amount of the wafer 2 with respect to the hand 10 can be acquired, for example, by analyzing an image of the wafer 2 held by the hand 10 taken by a camera, not shown in the figure. To acquire the misalignment amount of the wafer 2 with respect to the hand 10, a non-contact sensor can be installed at an appropriate position in the robot system 100. For example, two optical sensors are located at positions where the wafer 2 can cross. The optical axis of the optical sensor is perpendicular to the surface of the wafer 2 that is horizontal. To acquire the misalignment amount of the wafer 2, the controller 5 moves the hand 10 horizontally along a predetermined path while the hand is holding the wafer 2. In the process of this movement, coordinates of the hand 10 at the time when the wafer 2 blocks an optical path of each optical sensor and at the time when the blockage is released are stored. A virtual circle is calculated based on each of the stored coordinates, and the misalignment amount of the wafer 2 with respect to the hand 10 is calculated based on the position of the center of this virtual circle. Based on the misalignment amount, the position at which the robot 1 places the wafer 2 in the storage container 6 is corrected.

When the robot 1 places the wafer 2 in the storage container 6 at the corrected position, the same control as in the above embodiment can be used to stably avoid the adverse effects on positional accuracy due to backlash. In this case, the position where the hand 10 waits can be regarded as the relay position through which the hand 10 passes before reaching the position at which the wafer 2 is placed in the storage container 6 the position after correction). The above control can also be applied when the robot 1 places the wafer 2 in a location other than the storage container 6 (for example, a semiconductor processor).

While the positional misalignment detector 4 is detecting the positional misalignment of the wafer 2, the hand 10 may perform other work (for example, other wafer 2 transfer work) without waiting at the relay position. If the detection of the positional misalignment by the positional misalignment detector 4 is completed during other work, the hand 10 that has finished the work may pass through and reach the picking position without stopping at the relay position.

The control of the rotary table 41 and the line sensor 42, etc. provided by the positional misalignment detector 4 may be performed by the controller 5 of the robot 1 or by another computer. In other words, the misalignment amount may be calculated and acquired by the controller 5 itself or may be input to the controller 5 from outside.

The number of joints that the manipulator 11 includes, each with an axis in the vertical direction, is not limited to three, but may be one, two, or four or more. The hand of the manipulator 11 may be configured to be invertible around a horizontal flip axis.

A method of holding the wafer 2 by the hand 10 is optional and may employ various methods such as a passive grip, a suction grip, an edge grip, etc.

The control described in the above embodiments can also be applied when the robot 1 transfers substrates other than the wafer 2.

The functionality of the elements disclosed herein may be implemented using circuitry or processing circuitry which includes general purpose processors, special purpose processors, integrated circuits, ASICs (“Application Specific Integrated. Circuits”), conventional circuitry and/or combinations thereof which are configured or programmed to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

1. A controller for a substrate transfer robot, the controller that controls the substrate transfer robot comprising:
a hand capable of holding a substrate;
a joint whose axis is oriented in a vertical direction; and
a joint motor switchable in a direction of rotation to drive the joint, wherein
the controller corrects a position of the hand in at least one of the cases of picking the substrate and placing the substrate based on positional misalignment information indicating a positional misalignment of the substrate,
the controller controls the hand to pass through a relay position before the hand reaches a corrected position that is the position of the hand after correction, and
the controller controls the hand to reach the relay position by driving the joint in one direction by the joint motor, and the hand to reach the corrected position from the relay position by driving the joint in the same one direction only by the joint motor.

2. The controller for the substrate transfer robot according to claim 1, wherein
the relay position is distant from a range where the corrected position can take.

3. The controller for the substrate transfer robot according to claim 1, wherein
the one direction is the same no matter what the correction position is.

4. The controller for the substrate transfer robot according to claim 1, wherein
the positional misalignment information is information on the positional misalignment of the substrate set on a substrate aligner that is measured by the substrate aligner, and
based on the positional misalignment information, the controller corrects the position of the hand when the substrate set on the substrate aligner is picked.

5. The controller for the substrate transfer robot according to claim 4, wherein
the controller controls the substrate transfer robot so that the hand waits at the relay position after setting the substrate on the substrate aligner and before picking the substrate from the substrate aligner.

6. The controller for the substrate transfer robot according to claim 1, wherein
based on the positional misalignment information, the controller corrects the position of the hand when the substrate is set in a storage container.

7. The controller for the substrate transfer robot according to claim 6, wherein
the positional misalignment information is acquired with the substrate being held by the hand.

8. A robot system comprising:
the controller for the substrate transfer robot according to claim 1, and
the substrate transfer robot.

9. A control method for a joint motor applied to a substrate transfer robot, the substrate transfer robot comprising:
a hand capable of holding a substrate;
a joint whose axis is oriented in a vertical direction; and
a joint motor switchable in a direction of rotation to drive the joint, wherein,
the control method comprises:
correcting a position of the hand in at least one of the cases of picking the substrate and placing the substrate based on positional misalignment information indicating a positional misalignment of the substrate;
controlling the hand to pass through a relay position before the hand reaches a corrected position that is the position of the hand after correction; and
controlling the hand to reach the relay position by driving the joint in one direction by the joint motor, and the hand to reach the corrected position from the relay position by driving the joint in the same one direction only by the joint motor.
